(19) United States
(12) Patent Application Publication
(10) Pub. No.: US 2025/0029923 A1
(43) Pub. Date: Jan. 23, 2025

(54) SEMICONDUCTOR DEVICE

(71) Applicant: Socionext Inc., Kanagawa (JP)

(72) Inventor: Masato NAKOSHI, Yokohama (JP)

(21) Appl. No.: 18/772,766

(22) Filed: Jul. 15, 2024

(30) Foreign Application Priority Data
Jul. 21, 2023 (JP) 2023-119076

(51) Int. Cl. H01L 23/528; H01L 23/00

(52) U.S. Cl. CPC H01L 23/5283; H01L 23/528; H01L 23/5286; H01L 24/08; H01L 24/16; H01L 2224/08225; H01L 2224/16227; H01L 2924/301

(57) ABSTRACT

A semiconductor device includes a first pad; a first wiring connected to the first pad in a first direction in a plan view; a second wiring connected to the first pad in a second direction different from the first direction in the plan view; a second pad; a third wiring connected to the second pad in the first direction in the plan view; and a fourth wiring connected to the second pad in the second direction in the plan view. The second wiring is located between the third wiring and the first pad in the second direction, and the fourth wiring is located between the first wiring and the second pad in the second direction.

### CROSS-REFERENCE TO RELATED APPLICATION

The present application claims priority under 35 U.S.C. § 119 to Japanese Patent Application No. 2023-119076, filed Jul. 21, 2023, the contents of which are incorporated herein by reference in their entirety.

### BACKGROUND OF THE INVENTION

### 1. Field of the Invention

The present invention relates to a semiconductor device.

### 2. Description of the Related Art

In a semiconductor device, for example, in some cases a terminal such as a bump for supplying a power supply voltage or a ground voltage from the outside is arranged at a position overlapping with an input/output circuit. In addition, power supply wirings for supplying a power supply voltage or a ground voltage to the inside of the semiconductor device is sometimes arranged over a plurality of layers (See, for example, Japanese Unexamined Patent Application Publication No. 2009-164195, Japanese Unexamined Patent Application Publication No. 2012-234931, WO 2016/063458, U.S. Pat. Nos. 10,186,504, 7,554,133, 8,549,447, and 8,013,362).

### SUMMARY OF THE INVENTION

### Problems to be Solved by the Invention

Recently, with the miniaturization of an element structure of the semiconductor device, an interval between the arrangement of the bumps becomes narrow, and a space for the arrangement of the power supply wiring tends to become small. Consequently, when the number of the arrangements of the power supply wiring decreases, it may become difficult to efficiently supply the power supply voltage or the ground voltage to the semiconductor device.

The present invention has been made in consideration of the above points, and it is an object of the present invention to efficiently supply a power supply voltage or a ground voltage to a semiconductor device even in the semiconductor device having a narrow arrangement interval of pads to which bumps are connected.

### Means for Solving the Problem

According to an aspect of the present invention, a semiconductor device includes a first pad; a first wiring connected to the first pad in a first direction in a plan view; a second wiring connected to the first pad in a second direction different from the first direction in the plan view; a second pad; a third wiring connected to the second pad in the first direction in the plan view; and a fourth wiring connected to the second pad in the second direction in the plan view. The second wiring is located between the third wiring and the first pad in the second direction, and the fourth wiring is located between the first wiring and the second pad in the second direction.

### Effect of the Invention

According to the disclosed technique, even in a semiconductor device having a narrow arrangement interval of pads to which bumps are connected, a power supply voltage or a ground voltage can be efficiently supplied into the semiconductor device.

### BRIEF DESCRIPTION OF THE DRAWINGS

Other objects and further features of the present disclosure will be apparent from the following detailed description when read in conjunction with the accompanying drawings, in which:

FIG. 1 is a diagram showing an example of an outline of a semiconductor device according to a first embodiment;

FIG. 2 is a plan view showing another example of the semiconductor device;

FIG. 3 is a plan view showing an example of a layout of a power supply wiring in a circuit region of a semiconductor chip of FIG. 1;

FIG. 4 is of cross-sectional views showing an example of a cross section along the line X1-X1′ and an example of a cross section along the line Y1-Y1′of the semiconductor chip in FIG. 3;

FIG. 5 is a plan view showing another example of the layout of the power supply wiring in the circuit region of the semiconductor chip of FIG. 1; and

FIG. 6 is a plan view showing an example of a layout of a power supply wiring in a semiconductor device according to a second embodiment.

### DESCRIPTION OF PREFERRED EMBODIMENT

Hereinafter, the embodiment will be described with reference to the drawings. In the following, a reference numeral indicating a power supply voltage is also used as a reference numeral indicating a power supply wiring or a power supply terminal to which the power supply voltage is supplied. In the plan view and a cross-sectional view, a ratio of a width to a thickness of each wiring, a wiring spacing, a ratio of thicknesses of wiring layers, and a number of wiring lines to be wired at a position overlapping a bump BMP in the plan view are not limited to each figure.

### First Embodiment

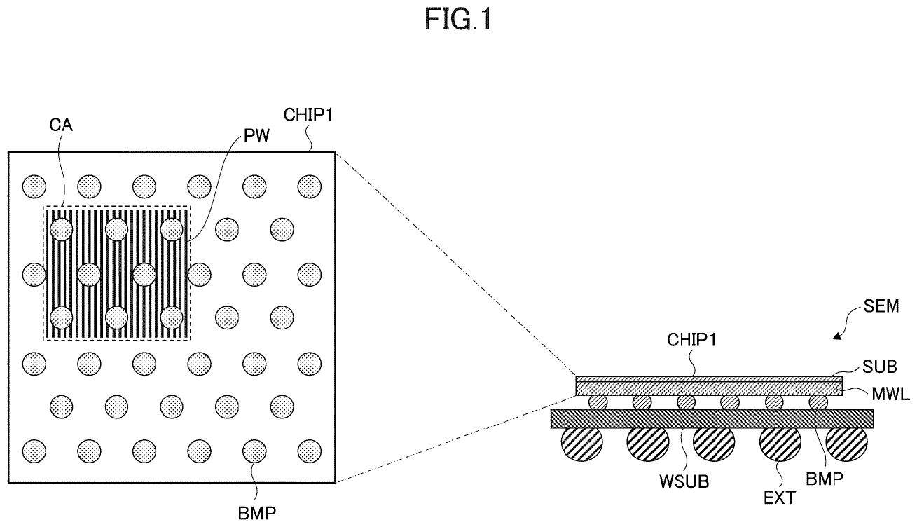

FIG. 1 shows an outline of a semiconductor device according to a first embodiment. For example, a semiconductor device SEM shown in FIG. 1 has a wiring substrate WSUB provided with an external connection terminal EXT and a semiconductor chip CHIP1 connected to the wiring substrate WSUB through a bump BMP, as shown in the cross-sectional view. The semiconductor chip CHIP1 is connected to the first surface of the wiring substrate WSUB through the bump BMP. The external connection terminal EXT is provided on the second surface which is an opposite surface of the first surface.

The semiconductor chip CHIP1 has a semiconductor substrate SUB on which elements such as transistors (not shown) are formed, and a multilayer wiring layer MWL provided on a bump BMP side of the semiconductor substrate SUB. As shown in the plan view, the semiconductor chip CHIP1 has a circuit area CA. The circuit area CA has a plurality of power supply wirings PW for supplying power supply voltages and ground voltages to elements such as transistors provided in the circuit area CA. Each power supply wiring PW is electrically connected to the bump BMP to which the power supply voltage and the ground voltages are supplied.

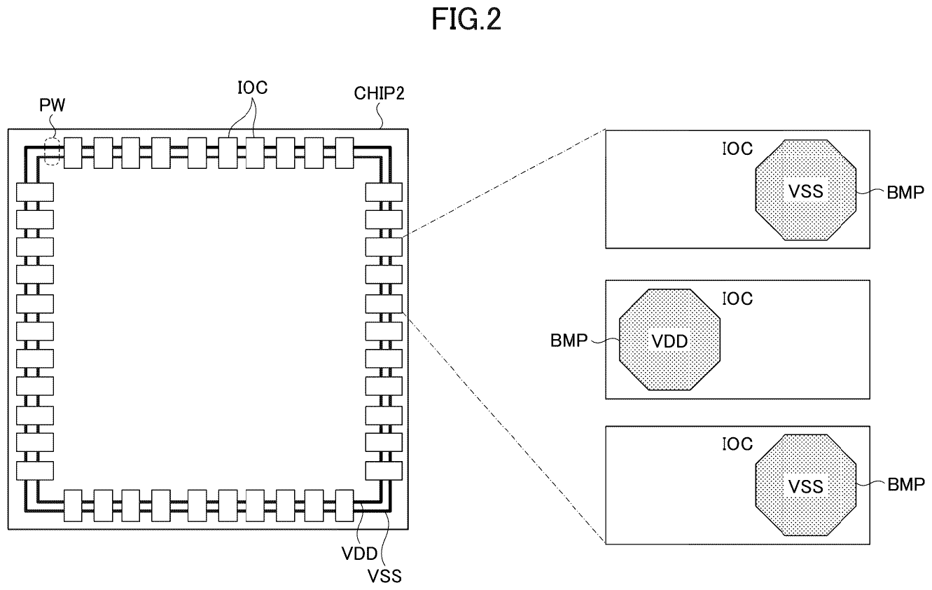

FIG. 2 shows another example of the semiconductor device. A semiconductor chip CHIP2 shown in FIG. 2 has an input/output cell IOC provided at a periphery of the chip and a plurality of power supply wirings PW for supplying a power supply voltage VDD and a ground voltage VSS to the input/output cell IOC. The power supply voltage VDD is an example of a first power supply voltage, and the ground voltage VSS is an example of a second power supply voltage.

The semiconductor chip CHIP2 has, for example, a bump BMP to which a power supply voltage VDD or a ground voltage VSS is supplied from the outside of the semiconductor chip CHIP2 at a position overlapping a region where each input/output cell IOC is provided in the plan view. The bump BMP to which the power supply voltage VDD is supplied is connected to the power supply wiring VDD of the power supply wirings PW. The bump BMP to which the ground voltage VSS is supplied is connected to the ground wiring VSS of the power supply wirings PW. Similar to the semiconductor chip CHIP1 of FIG. 1, the semiconductor chip CHIP2 may have a semiconductor substrate on which elements such as transistors (not shown) are formed, and a multilayer wiring layer provided on the bump BMP side of the semiconductor substrate.

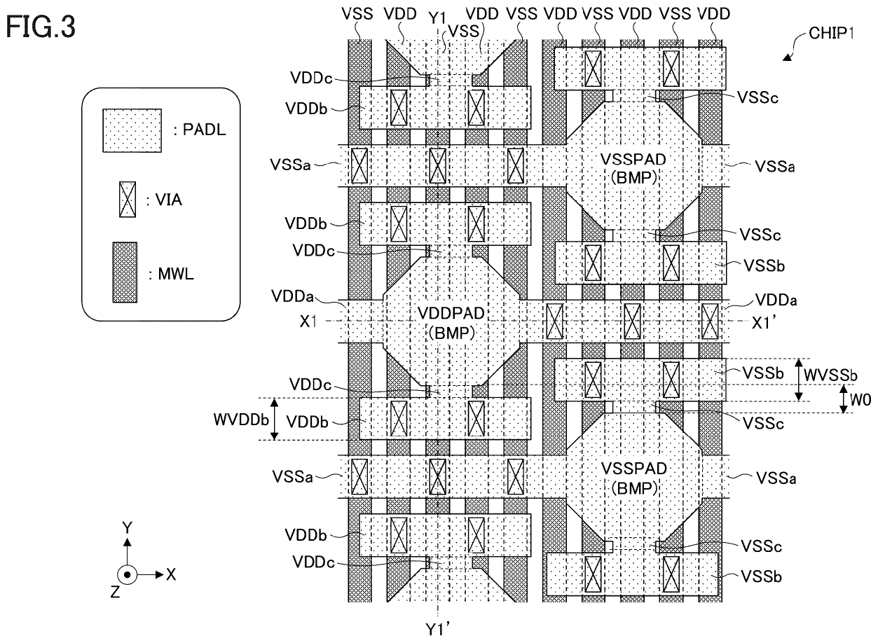

FIG. 3 shows an example of the layout of power supply wiring in the circuit area CA of the semiconductor chip CHIP1 of FIG. 1. As shown in FIG. 1, bumps BMP are arranged in a staggered pattern in the circuit area CA. Although an example of the layout of the power supply wiring of the semiconductor chip CHIP1 shown in FIG. 1 is shown in FIG. 3 and later, the layout technique shown in FIG. 3 and later may be applied to the layout of the power supply wiring of the semiconductor chip CHIP2 shown in FIG. 2.

The semiconductor chip CHIP1 has power supply pads VDDPAD, VSSPAD, and power supply wirings VDDa, VDDb, VDDc, VSSa, VSSb, and VSSc provided in a pad layer PADL arranged on the bump BMP side in the Z-direction in the thickness direction of the chip. The power supply pad VDDPAD is an example of a first pad. The power supply pad VSSPAD is an example of a second pad. The power supply wiring VDDa is an example of a first wiring, the power supply wiring VDDb is an example of a second wiring, and the power supply wiring VDDc is an example of a fifth wiring. The power supply wiring VSSa is an example of a third wiring, the power supply wiring VSSb is an example of a fourth wiring, and the power supply wiring VSSc is an example of a sixth wiring.

The power supply pad VDDPAD is provided at a position overlapping the bump BMP (not shown) to which the power supply voltage VDD is supplied in the plan view, and is connected to the bump BMP to which the power supply voltage VDD is supplied. The power supply pad VSSPAD is provided at a position overlapping the bump BMP (not shown) to which the ground voltage VSS is supplied in the plan view, and is connected to the bump BMP to which the ground voltage VSS is supplied. The power supply pad VDDPAD and the power supply pad VSSPAD are provided in a staggered pattern in the plan view, and are arranged at positions deviated from each other in a X direction and a Y direction. The bump BMP connected to the power supply pad VDDPAD is an example of a first bump, and the bump BMP connected to the power supply pad VSSPAD is an example of a second bump.

The semiconductor chip CHIP1 has power supply wirings VDD and VSS provided on the multilayer wiring layer MWL located on the opposite side of the bump BMP in the pad layer PADL. The pad layer PADL is an example of a first wiring layer, and the multilayer wiring layer MWL is an example of a second wiring layer different from the pad layer PADL. The power supply wirings VDD and VSS correspond to the power supply wirings PW in FIG. 1. The power supply wirings VDD and VSS extend in the Y direction and are alternately arranged at intervals in the X direction.

The power supply wiring VDD is an example of a seventh wiring and the power supply wiring VSS is an example of an eighth wiring. The X direction is an example of a first direction and the Y direction is an example of a second direction different from the X direction. The arrangement intervals of the power supply pads VDDPAD and VSSPAD and the widths and intervals of the power supply wirings VDDa, VDDb, VSSa, and VSSb are not limited to the example shown in FIG. 3. The number of power supply wirings VDD and VSS arranged at positions overlapping the power supply pads VDDPAD and VSSPAD in the plan view is not limited to the example shown in FIG. 3.

For example, the power supply pads VDDPAD, VSSPAD and the power supply wirings VDDa, VDDb, VDDc, VSSa, VSSb, VSSc are formed simultaneously by a semiconductor process for forming wirings in the pad layer PADL. For example, the power supply wirings VDD, VSS are formed simultaneously by a semiconductor process for forming wirings in the multilayer wiring layer MWL.

The power supply wirings VDDa are arranged along the X direction at a position across the power supply pad VDDPAD in the plan view and are connected to the power supply pad VDDPAD. The power supply wirings VDDb are arranged along the X direction on both sides in the Y direction of the power supply pad VDDPAD in the plan view and are adjacent to the power supply wirings VSSa at predetermined intervals in the Y direction. The power supply wirings VDDc are arranged on both sides in the Y direction of the power supply pad VDDPAD in the plan view and are provided between the power supply pad VDDPAD and the power supply wirings VDDb to connect the power supply wirings VDDb to the power supply pad VDDPAD.

The width of the power supply wirings VDDb in the Y direction and the width of the power supply wirings VDDc in the X direction are set to be less than or equal to the upper limit of the width of the power supply wirings in the layout rule. Therefore, the power supply wirings VDDb having a wide width in the X direction can be connected to the power supply pad VDDPAD without violating the layout rule. Each of the power supply wirings VDDa and VDDb is connected to the power supply wiring VDD of the multilayer wiring layer MWL through a plurality of vias VIA. The via VIA connecting the power supply wirings VDDa and VDDb to the power supply wiring VDD is an example of the first via.

The power supply wiring VSSa is arranged along the X direction at a position across the power supply pad VSSPAD in the plan view and is connected to the power supply pad VSSPAD. The power supply wiring VSSb is arranged along the X direction on both sides in the Y direction of the power supply pad VSSPAD in the plan view and is adjacent to the power supply wiring VDDa at predetermined intervals in the Y direction. The power supply wiring VSSc is arranged on both sides in the Y direction of the power supply pad VSSPAD in the plan view and is provided between the power supply pad VSSPAD and the power supply wiring VSSb to connect the power supply wiring VSSb to the power supply pad VSSPAD.

The width of the power supply wiring VSSb in the Y direction and the width of the power supply wiring VSSc in the X direction are set to be less than or equal to the upper limit of the width of the power supply wiring in the layout rule. Therefore, the power supply wiring VSSb having a wide width in the X direction can be connected to the power supply pad VSSPAD without violating the layout rule. Each of the power supply wirings VSSa and VSSb is connected to the power supply wiring VSS of the multilayer wiring layer MWL through a plurality of vias VIA. The via VIA connecting the power supply wirings VSSa and VSSb to the power supply wiring VSS is an example of a second via.

The power supply wiring VDDb is arranged at a position overlapping the power supply pad VSSPAD and the power supply wirings VSSb and VSSc when extended in the X direction. That is, a part of the position of the power supply wiring VDDb in the Y direction coincides with the position of the power supply wiring VSSb in the Y direction, and another part of the position of the power supply wiring VDDb in the Y direction coincides with the position of the power supply pad VSSPAD in the Y direction.

The power supply wiring VSSb is arranged at a position overlapping the power supply pad VDDPAD and the power supply wirings VDDb and VDDc when the power supply wiring VSSb is extended in the X direction. That is, a part of the position of the power supply wiring VSSb in the Y direction coincides with the position of the power supply wiring VDDb in the Y direction, and another part of the position of the power supply wiring VSSb in the Y direction coincides with the position of the power supply pad VDDPAD in the Y direction.

The interval WO between the power supply pads VDDPAD and VSSPAD in the Y direction is narrower than the width WVDDb of the power supply wiring VDDb in the Y direction and the width WVSSb of the power supply wiring VSSb in the Y direction. However, in this embodiment, the power supply wiring VDDb is arranged in the gap between the power supply pad VDDPAD and the power supply wiring VSSa, and the power supply wiring VSSb is arranged in the gap between the power supply pad VSSPAD and the power supply wiring VDDa.

Thus, the power supply wirings VDDb and VSSb having widths WVDDb and WVSSb larger than the intervals WO between the power supply pads VDDPAD and VSSPAD can be efficiently arranged in an open area where the power supply pads VDDPAD and VSSPAD and the power supply wirings VDDa and VSSa are not arranged.

Therefore, the power supply voltage VDD supplied from each bump BMP to the power supply pad VDDPAD can be efficiently distributed to the power supply wirings VDD of the multilayer wiring layer MWL through the power supply wirings VDDa and VDDb of the pad layer PADL. Similarly, the ground voltage VSS supplied from each bump BMP to the power supply pad VSSPAD can be efficiently distributed to the power supply wirings VSS of the multilayer wiring layer MWL through the power supply wirings VSSa and VSSb of the pad layer PADL. That is, when the bumps BMP are arranged in a staggered pattern, the power supply resistance of the path supplying the power supply voltage VDD and ground voltage VSS from each bump BMP to the power supply wirings VDD and VSS of the multilayer wiring layer MWL can be lowered.

On the other hand, for example, when auxiliary power supply wirings extending in the X direction are connected to the power supply wirings VDDc and auxiliary power supply wirings extending in the X direction are connected to the power supply wirings VSSc, each of the auxiliary power supply wirings becomes narrow or the wiring itself becomes difficult. Even when the auxiliary power supply wirings can be wired, the size of the via VIA connecting each of the auxiliary power supply wirings to the power supply wirings VDD and VSS of the multilayer wiring layer MWL becomes small.

In this case, the power supply voltages VDD and VSS supplied from the respective bumps BMP cannot be efficiently distributed to the power supply wirings VDD and VSS of the multilayer wiring layer MWL, and it becomes difficult to lower the power supply resistance from the respective bumps BMP to the power supply wirings VDD and VSS. Recently, the arrangement pitch of the bumps BMP tends to decrease with the miniaturization of the semiconductor process, and the space between the power supply wirings VDDa and VSSa tends to decrease. Therefore, it has become increasingly difficult to lower the power supply resistance.

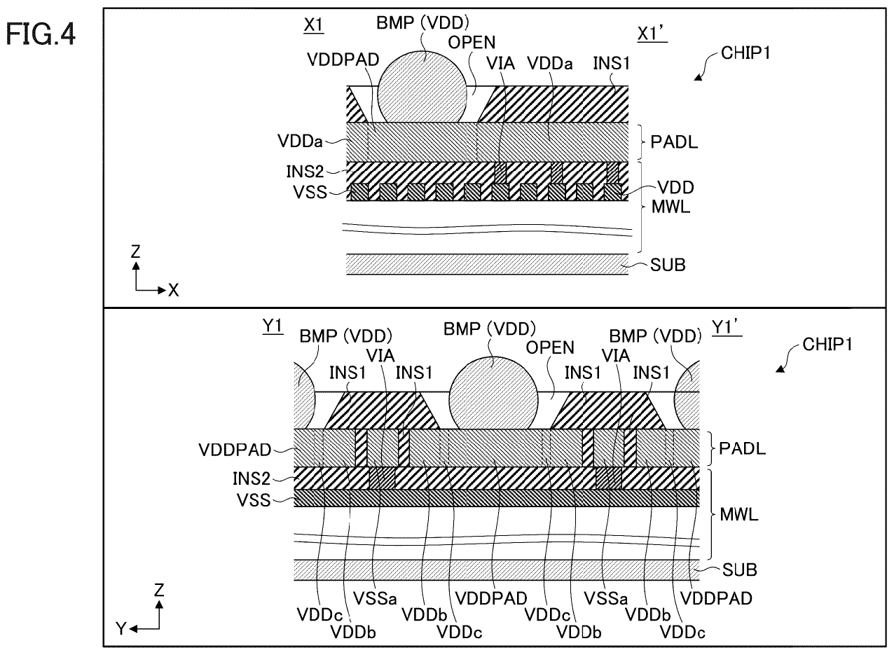

FIG. 4 shows an example of a cross section along the line X1-X1′ and a cross section along the line Y1-Y1′ in FIG. 3. In the cross section shown in FIG. 4, the cross section of the semiconductor chip CHIP1 in FIG. 1 is vertically inverted. In FIG. 4, elements such as transistors formed on the semiconductor substrate SUB are omitted. The semiconductor chip CHIP1 has a multilayer wiring layer MWL, a pad layer PADL, and an insulating film INS1 provided on the semiconductor substrate SUB in this order. The bump BMP is connected to a power supply pad VDDPAD exposed to an opening OPEN of the insulating film INS1. The insulating film INS1 may be formed by laminating a plurality of insulating films.

In the cross section along the line X1-X1′, a via VIA connected to the power supply wiring VDDa provided in the pad layer PADL, a power supply wiring VDD connected to the via VIA, and a power supply wiring VSS are formed in the insulating film INS2 on the pad layer PADL side of the multilayer wiring layer MWL. In addition to the power supply wiring, a signal wiring may be formed in the multilayer wiring layer MWL. In addition, in the multilayer wiring layer MWL, not only the wiring but also an element such as a transistor may be formed in a region on the semiconductor substrate SUB side of the insulating film INS2. The insulating film INS2 may be formed by laminating a plurality of insulating films.

In the cross section along the line Y1-Y1′, the insulating film INS2 on the pad layer PADL side of the multilayer wiring layer MWL is formed with a via VIA connected to the power supply wiring VSSa provided in the pad layer PADL and a power supply wiring VSS connected to the via VIA. The power supply wiring VSSa is arranged between two power supply wirings VDDb connected to two bumps BMP (VDD) respectively through the power supply wirings VDDa and VDDc.

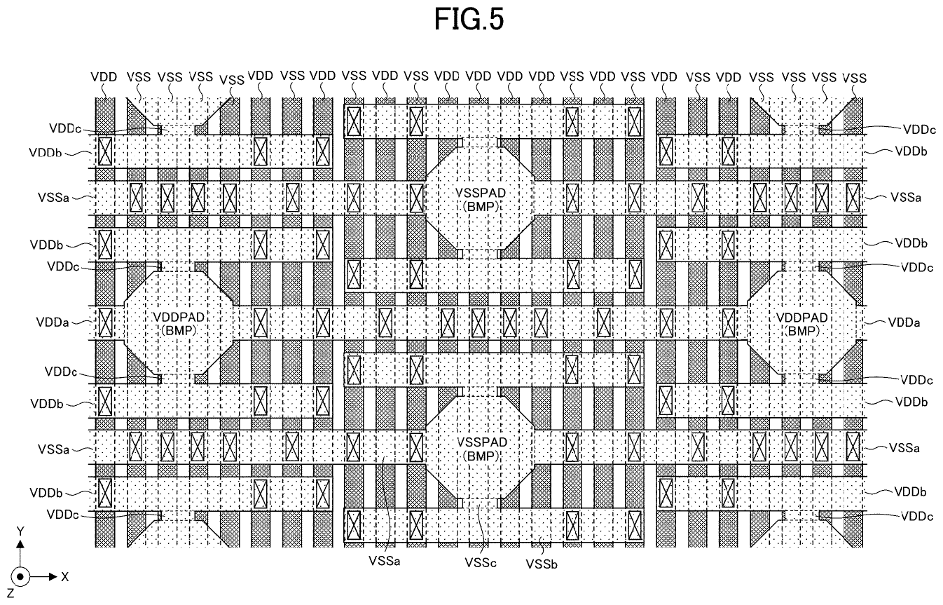

FIG. 5 shows another example of the layout of the power supply wiring in the circuit area CA of the semiconductor chip CHIP1 of FIG. 1. The same or similar layout as that of FIG. 3 will not be described in detail. The layout shown in FIG. 5 is similar to that of FIG. 3 except that the number of vias VIA connected to the power supply wirings VDDa and VDDb near the power supply pad VDDPAD in the X direction is different from the number of vias VIA away from the power supply pad VDDPAD, and the number of vias VIA connected to the power supply wirings VSSa and VSSb near the power supply pad VSSPAD in the X direction is different from the number of vias VIA away from the power supply pad VSSPAD.

The number of vias VIA connecting the power supply wirings VDDa and VDDb to the power supply wiring VDD increases as the distance from the power supply pad VDDPAD increases in the X direction. The number of vias VIA connecting the power supply wirings VSSa and VSSb to the power supply wiring VSS increases as the distance from the power supply pad VSSPAD increases in the X direction. Therefore, the arrangement density of the power supply wiring VDD increases as the distance from the power supply pad VDDPAD increases in the X direction, and the arrangement density of the power supply wiring VSS increases as the distance from the power supply pad VSSPAD increases in the X direction.

As a result, it is possible to suppress the difference between the ability to supply the power supply voltage VDD to the power supply wiring VDD that is arranged away from the power supply pad VDDPAD in the X direction in the plan view and the ability to supply the power supply voltage VDD to the power supply wiring VDD that is arranged near the power supply pad VDDPAD in the X direction. Similarly, it is possible to suppress the difference between the ability to supply the ground voltage VSS to the power supply wiring VSS that is arranged away from the power supply pad VSSPAD in the X direction in the plan view and the ability to supply the ground voltage VSS to the power supply wiring VSS that is arranged near the power supply pad VSSPAD in the X direction.

Since a uniform power supply voltage VDD can be supplied to each power supply wiring VDD and a uniform ground voltage VSS can be supplied to each power supply wiring VSS, the difference in the electrical characteristics (performance) of the circuit formed in the semiconductor chip CHIP1 depending on the positions of the power supply pads VDDPAD and VSSPAD can be suppressed. For example, the performance of the semiconductor device SEM is determined in accordance with the circuit having the lowest performance. In this embodiment, the performance of the semiconductor device SEM can be improved and the yield of the semiconductor device SEM can be improved because the deterioration of the performance of the circuit can be suppressed.

In the first embodiment, the power supply voltage VDD supplied from each bump BMP to the power supply pad VDDPAD can be efficiently distributed to the power supply wiring VDD of the multilayer wiring layer MWL through the power supply wiring VDDa and VDDb of the pad layer PADL. Similarly, the ground voltage VSS supplied from each bump BMP to the power supply pad VSSPAD can be efficiently distributed to the power supply wiring VSS of the multilayer wiring layer MWL through the power supply wiring VSSa and VSSb of the pad layer PADL. That is, when the bumps BMP are arranged in a staggered pattern, the power supply resistance of the path supplying the power supply voltage VDD and the ground voltage VSS from each bump BMP to the power supply wiring VDD and VSS of the multilayer wiring layer MWL can be lowered.

The power supply wiring VDDb is arranged between the power supply pad VDDPAD and the power supply wiring VSSa, and the power supply wiring VSSb is arranged between the power supply pad VSSPAD and the power supply wiring VDDa. As a result, the power supply wirings VDDb and VSSb having widths WVDDb and WVSSb larger than the interval WO between the power supply pads VDDPAD and VSSPAD can be efficiently arranged in an open area where the power supply pads VDDPAD and VSSPAD and the power supply wiring VDDa and VSSa are not arranged.

By setting the width of the power supply wiring VDDc in the X direction less than or equal to the upper limit value of the width of the power supply wiring in the layout rule, the power supply wiring VDDb having a wide width in the X direction can be connected to the power supply pad VDDPAD. Similarly, by setting the width of the power supply wiring VSSc in the X direction less than or equal to the upper limit value of the width of the power supply wiring in the layout rule, the power supply wiring VSSb having a wide width in the X direction can be connected to the power supply pad VSSPAD. In addition, the width of the power supply wiring VDDc in the X direction may be narrower than the width of the power supply wiring VDDb in the X direction, and the width of the power supply wiring VSSc in the X direction may be narrower than the width of the power supply wiring VSSb in the X direction.

A part of the position of the power supply wiring VDDb in the Y direction coincides with the position of the power supply wiring VSSb in the Y direction, and another part of the position of the power supply wiring VDDb in the Y direction coincides with the position of the power supply pad VSSPAD in the Y direction. As a result, the power supply wiring VDDb and VSSb can be efficiently arranged in an open area where the staggered power supply pads VDDPAD and VSSPAD and the power supply wirings VDDa and VSSa are not arranged.

The number of vias VIA connecting the power supply wirings VDDa and VDDb to the power supply wiring VDD increases as the distance from the power supply pad VDDPAD increases in the X direction. The number of vias VIA connecting the power supply wirings VSSa and VSSb to the power supply wiring VSS increases as the distance from the power supply pad VSSPAD increases in the X direction.

Thus, it is possible to suppress the difference between the supply capability of the power supply voltage VDD to the power supply wiring VDD arranged separated from the power supply pad VDDPAD in the X direction in the plan view and the supply capability of the power supply voltage VDD to the power supply wiring VDD arranged near in the X direction. Similarly, it is possible to suppress the difference between the supply capability of the ground voltage VSS to the power supply wiring VSS arranged separated from the power supply pad VSSPAD in the X direction in the plan view and the supply capability of the ground voltage VSS to the power supply wiring VSS arranged near in the X direction.

Since the uniform power supply voltage VDD can be supplied to each power supply wiring VDD and the uniform ground voltage VSS can be supplied to each power supply wiring VSS, the difference in the electrical characteristics (performance) of the circuit formed in the semiconductor chip CHIP1 depending on the positions of the power supply pads VDDPAD and VSSPAD can be suppressed. For example, the performance of the semiconductor device SEM is determined according to the circuit having the lowest performance. In this embodiment, the performance of the semiconductor device SEM can be improved and the yield of the semiconductor device SEM can be improved because the deterioration of the performance of the circuit can be suppressed.

### Second Embodiment

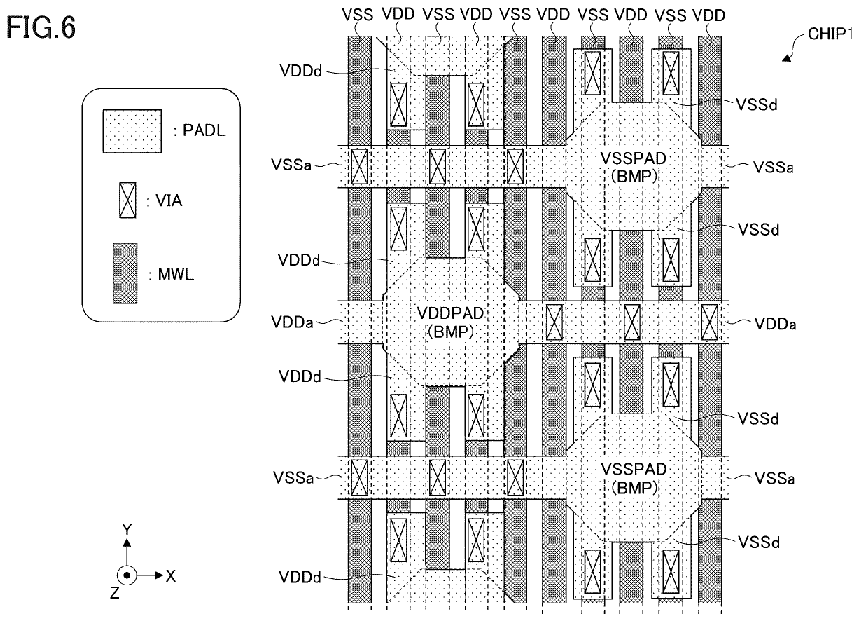

FIG. 6 shows an example of a layout of power supply wiring in a semiconductor device according to a second embodiment. A detailed description of the same or similar layout as that in FIG. 3 will be omitted. The layout shown in FIG. 6 is the same as that of FIG. 3 except that the power supply wirings VDDd are arranged instead of the power supply wirings VDDb and VDDc, and the power supply wirings VSSd are arranged instead of the power supply wirings VSSb and VSSc.

The power supply wirings VDDd are provided on both sides of the power supply pad VDDPAD in the Y direction by two lines extending in the Y direction, and their tips are adjacent to the power supply wirings VSSa at predetermined intervals. The power supply wirings VSSd are provided on both sides of the power supply pad VSSPAD in the Y direction by two lines extending in the Y direction, and their tips are adjacent to the power supply wirings VDDa at predetermined intervals. The widths of the power supply wirings VDDd and VSSd in the X direction are set to be less than or equal to the upper limit of the width of the power supply wirings in the layout rule.

By extending the power supply wirings VDDd and VSSd in the Y direction, the length of the via VIA connected to the power supply wirings VDDd and VSSd in the Y direction can be made longer than the length of the via VIA connected to the power supply wirings VDDb and VSSb in the Y direction in FIG. 3. Therefore, the power supply resistance of the path that supplies the power supply voltage VDD and the ground voltage VSS to the power supply wirings VDD and VSS of the multilayer wiring layer MWL from each bump BMP can be further lowered compared to that of the layout in FIG. 3.

As described above, the same effect as that of the first embodiment can be obtained also in the second embodiment. For example, the power supply voltage VDD supplied from the bump BMP to the power supply pad VDDPAD can be efficiently distributed to the power supply wirings VDD, and the ground voltage VSS supplied from the bump BMP to the power supply pad VSSPAD can be efficiently distributed to the power supply wirings VSS. That is, compared to the case where the power supply wirings VDDb and VSSb are not provided, the power supply resistance of the path supplying the power supply voltage VDD and ground voltage VSS from each bump BMP to the power supply wirings VDD and VSS of the multilayer wiring layer MWL can be further lowered.

Furthermore, in the second embodiment, by extending the power supply wirings VDDd and VSSd in the Y direction, the length in the Y direction of the vias VIA connected to the power supply wirings VDDd and VSSd can be made longer than the length in the Y direction of the vias VIA connected to the power supply wirings VDDb and VSSb in FIG. 3. Therefore, the power supply resistance of the path that supplies the power supply voltage VDD and the ground voltage VSS to the power supply wiring VDD and VSS of the multilayer wiring layer MWL from each bump BMP can be further lowered compared to that of the layout in FIG. 3.

Although the present invention has been described based on the above embodiments, the present invention is not limited to the requirements shown in the above embodiments. With regard to these points, various changes, modifications, substitutions, additions, deletions, and combinations are possible within the scope of claims, and may be appropriately defined according to the application form thereof.

What is claimed is:

1. A semiconductor device comprising:
a first pad;
a first wiring connected to the first pad in a first direction in a plan view;
a second wiring connected to the first pad in a second direction different from the first direction in the plan view;
a second pad;
a third wiring connected to the second pad in the first direction in the plan view; and
a fourth wiring connected to the second pad in the second direction in the plan view, wherein,
the second wiring is located between the third wiring and the first pad in the second direction, and
the fourth wiring is located between the first wiring and the second pad in the second direction.

2. The semiconductor device according to claim 1, wherein
the first pad and the second pad are arranged at positions deviated from each other in the first direction and the second direction.

3. The semiconductor device according to claim 1, wherein
an interval between the first pad and the second pad in the second direction is narrower than a width of the second wiring in the second direction.

4. The semiconductor device according to claim 3, wherein
an interval between the first pad and the second pad in the second direction is narrower than a width of the fourth wiring in the second direction.

5. The semiconductor device according to claim 1, wherein
the first pad is supplied with a first power supply voltage, and
the second pad is supplied with a second power supply voltage different from the first power supply voltage.

6. The semiconductor device according to claim 1 further comprising:
a fifth wiring provided between the first pad and the second wiring and connecting the first pad and the second wiring; and
a sixth wiring provided between the second pad and the fourth wiring and connecting the second pad and the fourth wiring, wherein
a width of the fifth wiring in the first direction is narrower than a width of the second wiring in the first direction, and
a width of the sixth wiring in the first direction is narrower than a width of the fourth wiring in the first direction.

7. The semiconductor device according to claim 1, wherein
a part of a position of the second wiring in the second direction coincides with a position of the fourth wiring in the second direction.

8. The semiconductor device according to claim 1, further comprising:
a seventh wiring and an eighth wiring provided in a second wiring layer that is different from a first wiring layer, in which the first wiring, the second wiring, the third wiring, and the fourth wiring are provided, the seventh wiring and the eight wiring being arranged at intervals in the first direction and extending in the second direction;
one or more first vias each connecting the first wiring and the second wiring to the seventh wiring; and
one or more second vias each connecting the third wiring and the fourth wiring to the eighth wiring, wherein
a number of the first vias each connecting the first wiring and the second wiring to the seventh wiring increases as a distance from the first pad increases in the first direction, and
a number of the second vias each connecting the third wiring and the fourth wiring to the eighth wiring increases as a distance from the second pad increases in the first direction.

9. The semiconductor device according to claim 1, wherein
a plurality of second wirings extending in the second direction are provided on each side of both sides of the first pad in the second direction, each of the second wirings being the second wiring, and
a plurality of fourth wirings extending in the second direction are provided on each side of both sides of the second pad in the second direction, each of the fourth wirings being the fourth wiring.

10. The semiconductor device according to claim 1 further comprising:
a first bump connected to the first pad; and
a second bump connected to the second pad.
